(19) United States
(12) Patent Application Publication
(10) Pub. No.: US 2016/0095226 A1
(43) Pub. Date: Mar. 31, 2016

(54) Printed Timer Label

(71) Applicants: Per BRÖMS, Linkoping (SE); Robert FORCHHEIMER, Linkoping (SE)

(72) Inventors: Per BRÖMS, Linkoping (SE); Robert FORCHHEIMER, Linkoping (SE)

(73) Assignee: THIN FILM ELECTRONICS ASA, Oslo (NO)

(21) Appl. No.: 14/870,561

(22) Filed: Sep. 30, 2015

Related U.S. Application Data
(60) Provisional application No. 62/058,020, filed on Sep. 30, 2014.

(51) Int. Cl. H05K 1/18; H01M 10/42

(52) U.S. Cl. CPC H05K 1/189; H05K 1/182; H01M 10/425

(57) ABSTRACT

A printed timer label including a substrate, a printed battery on the substrate, a printed load resistance configured to control a discharge time of the printed battery, and printed voltage comparison circuitry connected to the printed battery and configured to provide an output signal depending on the output voltage of the printed battery relative to a predetermined threshold value.

### CROSS REFERENCE TO RELATED APPLICATION

This application claims the benefit of U.S. Provisional Patent Application No. 62/058,020, filed on Sep. 30, 2014, incorporated herein by reference as if fully set forth herein.

### FIELD OF THE INVENTION

The present disclosure generally relates to the field(s) of printed electronic circuitry. More specifically, embodiments of the present invention pertain to a printed timer circuit, especially to a printed timer circuit using a voltage differential.

### DISCUSSION OF THE BACKGROUND

The development of technology for printed electronic circuits enable printed electronic devices such as smart labels. The use of printing of functional inks allows the introduction of electronic functionality to labels and other disposable products in a cheap and large scale manufacturing manner.

One application for this technology is timer labels in which an irrevocable activation of the timer starts a countdown and which in some way indicates the end of the time.

One way of providing such timer label using printing technique is to print, on a substrate, all components and connections needed to function with an integrated circuit subsequently mounted on the substrate. The integrated circuit provides, when activated, a time calculation according to predefined settings, and activates an indication means when the set time is reached. Such indication means may for instance be a display or lights, such as a LED.

The use of an integrated circuit however has some disadvantages in such application. The integrated circuit needs to be mounted on the substrate post printing, and further needs programming for setting the time interval of the timer. This makes such timer label complicated and expensive to produce.

Consequently, there is a need of simpler, more cost-efficient and printing friendly solution to provide a timer label.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

It is an object of the present invention to provide an improved solution that alleviates the mentioned drawbacks. Furthermore, it is an object to provide a timer label not using an integrated circuit.

The present invention therefore relates to a printed timer label including a substrate, a printed battery on the substrate, a printed load resistance configured to control a discharge time of the printed battery, and printed voltage comparison circuitry connected to the printed battery and configured to provide an output signal depending on the output voltage of the printed battery relative to a predetermined threshold value. The present printed timer label may provide a cost-effective timer label enabling large scale manufacturing. Since no monolithic integrated circuit is needed for the timer function, all components of the timer label may be printed on the substrate using conventional electronics printing techniques. Further, the present timer label may be produced with lower costs compared to a timer label that includes a monolithic integrated circuit. The printed resistance may comprise one or more electronic components providing a load resistance to the battery. Depending on the size of the load resistance, the load on the battery may vary, and as a result, the discharge time of the battery may vary.

In various embodiments, the printed timer label may further comprise an integrated circuit configured to provide functionality in the timer label other than the timer function. Such an integrated circuit may be on the substrate and connected to the other components and circuitry on the substrate (e.g., by one or more traces on the substrate, each of which may be or comprise a printed trace). The printed timer label may therefore form part of a hybrid system further comprising the integrated circuit.

The resistance may, in one embodiment, comprise a resistor providing a load resistance (e.g., on the battery). An output of the voltage comparison circuitry may be configured to switch (e.g., change state) when the output voltage of the battery reaches a threshold level or voltage. The voltage comparison circuitry may then provide a time elapsed signal, indicating that the time interval of the timer label has ended. In one embodiment, the voltage comparison circuitry may be or comprise a differential amplifier. In an alternative embodiment, the voltage comparison circuitry may be or comprise an operational amplifier.

In various embodiments of the present printed timer circuit, the printed resistance comprises two or more resistors in parallel, and at least one switch configured to select a total resistance of the printed resistance. In such a configuration, the load resistance may be selected using the switch. The time interval of the printed timer label may thereby be selected prior to use.

In one embodiment, the timer label is configured for one-time use (e.g., is non-reusable). The time interval of the timer label may be selected prior to activation of the timer label. The selection may be permanent. The selection (e.g., the activation of a switch) may comprise closing or breaking a circuit. Breaking the circuit may mean splitting or cutting a conductor. When the resistance comprises two resistors in parallel and the switch(es) configured to select a total resistance of the printed resistance, one of the at least one switch may be in series with one of the resistors. A selection of load resistance may be made by opening or closing switch, providing a load resistance equal to the resistance of one of the two resistors (e.g., an open switch configuration) or the two parallel resistors combined (e.g., a closed switch configuration).

In various embodiments, the at least one switch may further comprise a pull tag and two activation pads, and may be configured to be activated by removal of the pull tag and compression of the activation pads towards each other (or to electrodes in the switch) to close a circuit. The activation pads may further be provided with an adhesive to be fixed to each other (or to the electrodes) after compression, providing a permanent closure of the circuit. The pull tag may provide insulation between the activation pads (or between the activation pads and the electrodes in the switch). The timer label may be provided with one or more switches each comprising such a pull tag. The timer label may thereby be prepared for pulling of one or more pull tags for closing one or more switches to select one of a plurality of selectable load resistances and timer intervals for the timer label. Similarly, the timer label may be provided with one or more conductors for breakage of the same to activate the one or more switches for selection of the load resistance and timer interval.

In one embodiment, a switch may be arranged in series with each of the parallel resistors. By having a switch in series with each resistor, further selectable load resistances may be provided. In another embodiment as above with two parallel resistors, one switch in series with one of the resistors may provide one further selectable load resistance.

In one or more embodiments, the timer label may further comprise an indication device connected to the output of the differential amplifier. The indication device may be configured to react on the output signal/time elapsed signal from the differential amplifier (e.g., by indicating that the time interval has elapsed). For example, when the output of the comparison circuit switches as a reaction to the battery output voltage reaching the threshold voltage, the indication device may switch to a time elapsed indication state. The indication device may be a light source or an electronic display. The time elapsed indication state may for the light source be an active light signal (e.g., a fixed light or flashing light). For an electronic display, the time elapsed indication state may comprise display of a text or changing the text on the display. In various embodiments, the display or light source may also be printed on the substrate, for instance using screen printing.

These and other advantages of the present invention will become readily apparent from the detailed description of various embodiments below.

### BRIEF DESCRIPTION OF THE DRAWINGS

The invention will in the following be described in more detail with reference to the enclosed drawings, wherein:

FIG. 1 shows an exemplary schematic block diagram of a timer label circuit according to one or more embodiments of the invention;

FIG. 2 shows an exemplary schematic circuit diagram of a timer label according to one or more embodiments of the invention;

FIG. 3A shows a first exemplary schematic circuit diagram of a load resistance circuit according to one or more embodiments of the invention;

FIG. 3B shows another exemplary schematic circuit diagram of a load resistance circuit according to one or more embodiments of the invention;

FIG. 4 shows an exemplary diagram illustrating a timer interval of a timer label according to one or more embodiments of the invention;

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and materials have not been described in detail so as not to unnecessarily obscure aspects of the present invention.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

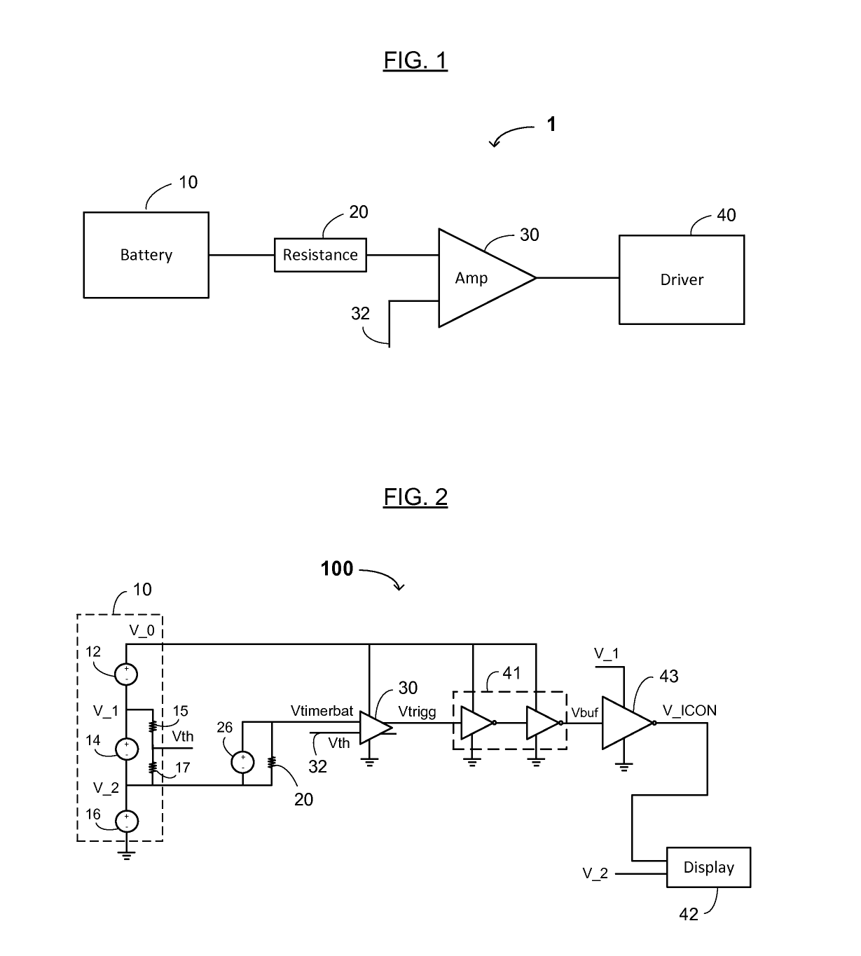

FIG. 1 illustrates an exemplary block diagram of a circuit 1 in the printed timer label according to one or more embodiments of the present invention. A battery 10 is configured to, when activated, provide power to voltage comparison circuitry. In one embodiment, the voltage comparison circuitry comprises a differential amplifier 30. A load resistance 20 is connected to the battery 10 and an input to the differential amplifier 30. The size of the load resistance 20 determines the amount of power needed to power the circuit 1. Consequently, the load resistance 20 determines the discharge time of the battery 10.

The battery 10 has a predetermined power capacity. In one embodiment, the battery provides a voltage of 3V to the differential amplifier 30 (e.g., through the resistance 20) when activated. The differential amplifier 30 detects the voltage provided by the battery 10 and compares it with a threshold voltage 32. In one embodiment, the threshold voltage 32 is 1.5V, and in another embodiment, the threshold voltage 32 is 4.5V, but the threshold voltage 32 may be any voltage that, when compared with the voltage from the resistance 20, provides a desired time period for the circuit 1. For example, the threshold voltage 32 may be a voltage that is 10-90% of the nominal or initial voltage from the resistance 20, or any value or range of values therein (e.g., 50-80%, and in one example, 75%).

When the battery 10 discharges current or power, the voltage level(s) from the battery 10 decrease over time. When the voltage level from the resistance 20 reaches the threshold voltage 32, the output from the differential amplifier 30 switches state, and the printed timing label provides a “timer elapsed” signal (e.g., on a display or other “time elapsed” indicator 40). Depending on the size of the load resistance 20, the time interval of the label (i.e. the time from activation of the label until the voltage from the resistance 20 reaches the threshold voltage 32) may differ or vary. The time interval may be, for example, in seconds (e.g., 1-300 seconds), minutes (e.g., 1-300 minutes), or hours (e.g., 1-100 hours, such as 10 hours or 72 hours).

The differential amplifier 30 is connected to the indicator 40. In various embodiments, the indicator 40 may comprise a light source (e.g., an LED), an auditory indicator (e.g., a buzzer, bell, chime, or series of tones), or a display (e.g., a visual display). When the “timer elapsed” signal is provided, the indicator 40 indicates to a user that the time interval has ended.

An example of a more detailed design 100 of the circuit 1 is seen in FIG. 2, which illustrates one or more embodiments of the invention. The circuit 100 comprises the differential amplifier 30 and a gain element (e.g., an inverter chain 41) configured to amplify the “timer elapsed” signal and enable a relatively fast switch time for the display 42. A large inverter 43 at an output of the chain 41 is configured to drive a high capacitive load of the display 42. The driver 43, which receives an intermediate voltage V_1 from the battery 10 and which may output a drive signal V_ICON at a relatively high current, is useful when the display 42 comprises an electro-chromic display. In one example, the intermediate voltage V_1 from the battery 10 is 6 V or about 6 V.

The display 42 may have a COM node connected to a low-power rail (i.e., a relatively low voltage V_2 output by the battery 10). In one example, the intermediate voltage V_1 from the battery 10 is 3V or about 3V. When the driver 43 of the display 42 is connected to a 6V power rail (e.g., V_1), it is possible to have a 3V or −3V potential over the display 42.

The battery 10 comprises one or more cells and a plurality of resistors that function as a voltage divider, and outputs at least three voltages (e.g., a high voltage, a low voltage, and a threshold voltage between the high and low voltages). In the embodiment shown in FIG. 2, the battery 10 comprises first, second and third cells 12, 14 and 16 connected in series, and first and second resistors 15 and 17. At least one of the cells 12, 14 and 16 may be connected to a ground potential. Each of the cells 12, 14 and 16 may generate the same voltage as or a different voltage from the other cells. In one example, each of the cells 12, 14 and 16 generates a voltage of 3V (e.g., each of the cells 12, 14 and 16 comprises a printed lithium battery), but the invention is not limited to this value. For example, each of the cells 12, 14 and 16 may generate a voltage of from 1V to 9V, or any value or range of values therein. As a result of the series arrangement of the cells 12, 14 and 16, the battery outputs a high voltage V_0 (e.g., 9V), an intermediate voltage V_1 (e.g., 6V), and a low voltage V_2 (e.g., 3V). The first and second resistors 15 and 17 are connected in series between V_1 and V_2, and a threshold voltage Vth is output from the node between the resistors 15 and 17. However, this arrangement is also not required, and the first and second resistors 15 and 17 may be connected in series between any two voltages generated by the battery 10 (e.g., V_0 and V_2), or between one of the voltages generated by the battery 10 (e.g., V_1 or V_2) and a ground potential.

The embodiment shown in FIG. 2 further includes a timer battery cell 26, configured to boost the voltage V_2 by an amount sufficient to make the input Vtimerbat to the differential amplifier 30 greater than the reference voltage Vth 32 (e.g., from 1.1 to 10 times greater, or any value or range of values therein, such as 1.25 to 2 times greater). In various examples, the timer battery cell 26 has a voltage equal to the voltage of cell 16 or cell 14 (e.g., 3V). Thus, the timer battery cell 26 may comprise a cell that is identical or substantially identical to one or more of the cells 12, 14 and 16 in the battery 10 (e.g., a 3V printed lithium battery).

The discharge time of the timer (i.e., the timer interval) is determined by the load or resistance of the load resistor 20. The resistance value of the load resistor 20 depends on the voltage(s) output by the battery 10 (including the threshold voltage Vth) and the desired time interval to be counted by the circuit 100, and optionally, the voltage output by the timer battery cell 26, but in general, the load resistor 20 may have a resistance of from 0.1 to 100 kΩ, or any value or range of values therein (e.g., 1.5 kΩ).

The threshold voltage 32 provided to the differential amplifier 30 is determined by the resistors 15 and 17. Thus, the resistance values of the first and second resistors 15 and 17 should be selected so that the threshold voltage Vth is less than the voltage V_2 from the battery 10 plus the voltage of the timer battery cell 26 (i.e., Vtimerbat). The difference between Vtimerbat and the threshold voltage Vth, and the rate of the voltage drop in Vtimerbat caused by the load resistor 20, determine the timing interval of the printed timer circuit 100. In various examples, the ratio of the resistance value of the first resistor 15 to the resistance value of the second resistor 17 may be from 1:100 to 100:1, or any value or range of values therein (e.g., from 1:10 to 10:1, and in some specific examples, 1:4 or 1:1). Each of the first and second resistors 15 and 17 may have a resistance of from 1 to 10,000 kΩ, or any value or range of values therein (e.g., 10-1000 kΩ). In one example, the first resistor 15 may have a resistance of 100 kΩ, and the second resistor 17 may have a resistance of 400 kΩ. In another example, the first and second resistors 15 and 17 may have the same resistance (e.g., 100 kΩ or 400 kΩ).

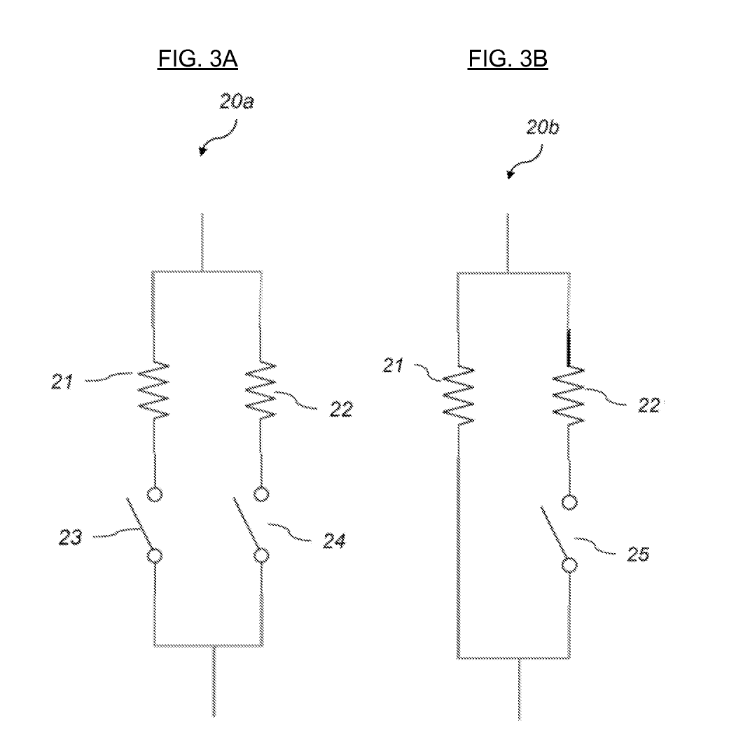

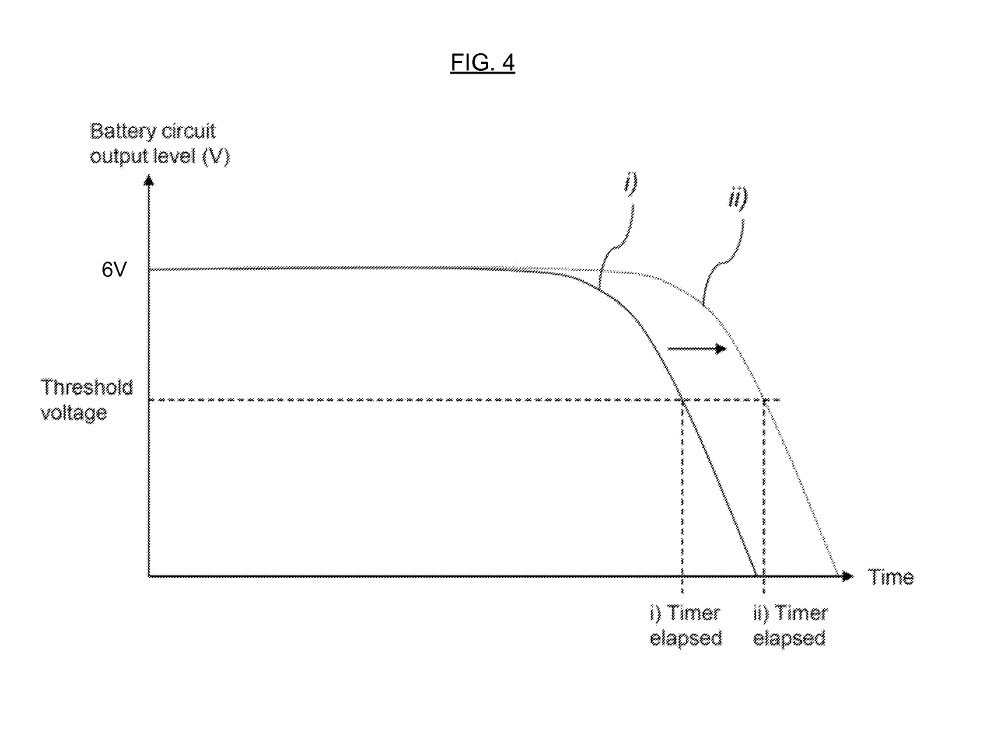

In various embodiments, the load resistance 20 in the circuit 100 may be selectable and/or programmable. FIGS. 3A and 3B show exemplary embodiments of a selectable and/or programmable load resistance 20a and 20b, respectively. In FIGS. 3A and 3B, the load resistances 20a and 20b comprise two parallel resistors 21, 22. The resistors 21, 22 are connected to at least one switch (switch 25 in FIG. 3B, and switches 23, 24 in FIG. 3A) for activation. By selecting one or both of the resistors 21, 22, different discharge times can be obtained. The load resistor 20 in the timer label circuit 100 shown in FIG. 2 may be replaced with either of the load resistances 20a or 20b.

As seen in FIG. 3A, a two switch solution 20a is provided, enabling possible resistance values equal to resistor 21, resistor 22 or resistor 21 in parallel with resistor 22. Hence, the two switch/two resistor arrangement 20a enables three different resistance values, providing three different time intervals for the timer label. For example, if switch 23 is closed and switch 24 is open, the load resistance 20a is the resistance of resistor 21. If switch 23 is open and switch 24 is closed, the load resistance 20a is the resistance of resistor 22. If both switches 23, 24 are closed, the load resistance 20a is the resistance of resistor 21 in parallel with resistor 22.

In the embodiment of FIG. 3B, two possible resistance values are enabled using one switch 25. For example, when switch 25 is open, the load resistance 20b is the resistance of resistor 21, and when the switch 25 is closed, the load resistance 20b is the resistance of resistor 21 in parallel with resistor 22.

Both embodiments comprising load resistance arrangement 20a or 20b provide a selectable or programmable timer interval. When the power capacity (e.g., output voltage[s] and/or current[s]) of the battery 10 and the threshold voltage 32 are known, the load resistance alternatives in either arrangement 20a or 20b may be selected to provide various time interval options.

The timer circuit 100 uses voltages in the middle or center of the 0V-to-full rail voltage (e.g., 9V) range for the inputs to the differential amplifier 30 to provide or ensure better predictability and/or control of the timing interval. For example, the rate of decay of the timer battery cell 26 is relatively linear in the range of 4V to 5V, whereas it is relatively less linear closer to 0V (or, alternatively, 3V) or the initial full-rail voltage output from the timer battery cell 26 (e.g., 6V). However, in one or more alternative embodiments, to omit the timer battery cell 26, the battery voltage input Vtimerbat received by the differential amplifier 30 may be the intermediate voltage V_1 or, when the battery has only one or two cells, the high voltage V_0.

Since the circuits 1 and 100 according to FIGS. 1 and 2 can provide a timer label 1 without an integrated circuit (e.g., fabricated on a monolithic silicon chip or die), all parts of the circuit 1 can be printed using thin film printing technique on a substrate. For example, the entire circuit as illustrated in FIG. 2 can be printed, excluding the display 42. However, the display 42 may be made using thin film processing, which is a relatively mature and low-cost technology. The substrate (which may also include the display 42) may be a flexible substrate, enabling a large variety of applications of the timer label. This enables cost-effective manufacturing of such timer labels, including low cost mass production of disposable and/or single-use timer labels. For example, the label may be used in medical applications such as certain medical procedures (e.g., disinfection of surfaces), administration of certain pharmaceuticals, medical kits or devices such as pregnancy tests, or personal hygiene (e.g., toothbrushing), food applications such as expiration labels or cooking timers, industrial or household applications such as application of adhesives or other chemicals, application of electrical or other power to a one-time (e.g., disposable) device or apparatus, etc.

FIG. 4 is a graph illustrating an exemplary process of using the present printed timer label. In this example, a low voltage from the battery 10 (e.g., Vtimerbat or V_2, which in one example is 6V) is provided to the differential amplifier 30. Following the solid line i), the low voltage from the battery 10 starts to decrease when the power capacity of the battery 10 drops. When the voltage received by the differential amplifier 30 reaches the threshold voltage level Vth, which for instance may be 4.5V, the output of the differential amplifier switches to a “timer elapsed” state.

The actual time between the start of the timer interval and the end (timer elapsed) depends on the power capacity of the battery 10 and the load on the battery 10. With a predetermined power capacity, the load on the battery 10 may be selected to provide a desired timer interval. As further seen in FIG. 4, the timer interval can be extended (e.g., switched to a longer elapsed time) by lowering the load on the battery 10 (e.g., decreasing the resistance of the load resistor 20). The dashed line ii) illustrates a timer interval where the load is lower, and hence the elapsed time ii) is longer.

With reference to FIG. 3B, the solid line i) in FIG. 4 may correspond to a selected load resistance 20b providing a resistance equal to resistor 21 (i.e., the switch 25 remains open). Further, the dashed line ii) in FIG. 4 may correspond to a selected load resistance 20b providing a resistance equal to resistor 21 in parallel with resistor 22 (i.e., the switch 25 is closed). The latter situation provides a lower load resistance 20b, which provides a longer timer interval (elapsed time ii)).

By providing a timer label with two or more selectable load resistances, different timer intervals may be enabled with the same timer label. The timer label 1 may therefore comprise one or more selection switches 23, 24, 25 to select the load resistance, and thereby set the timer interval from among a plurality of selectable timer intervals.

The selection switches 23, 24 and 25 can be one-time (programmable) switches that will remain permanently in the selected position. They can be either an OFF-to-ON type switch or an ON-to-OFF type switch. An OFF-to-ON type switch may comprise a pull tag implementation with a conductive adhesive on contact pads, such that when the user pulls the tag and then presses on an indicated area on the timer label to close the circuit, the switch is permanently closed. An ON-to-OFF implementation may comprise a printed conductive line in which the user scratches or cuts the conductor and breaks the circuit, or severs the conductor and breaks the circuit when the pull tag is pulled. The selector switch is then permanently open. The type of switch to be used depends on the application in which the timer label will be used.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. In the drawings and specification, there have been disclosed various embodiments and examples of the invention and, although specific terms are employed, they are used in a generic and descriptive sense only and not for the purpose of limitation. The embodiments were chosen and described in order to best explain the principles of the invention and its practical application. It is intended that the scope of the invention be defined by the claims appended hereto and their equivalents.

What is claimed is:

1. A printed timer label, comprising:
a substrate,
a printed battery on the substrate,
a printed load resistance on the substrate, configured to control a discharge time of the printed battery, and
printed voltage comparison circuitry connected to the printed battery and configured to provide an output signal depending on an output voltage of the printed battery relative to a predetermined threshold value.

2. The printed timer label according to claim 1, wherein the printed load resistance comprises two or more resistors in parallel and at least one switch configured to select a total resistance of the printed load resistance.

3. The printed timer label according to claim 2, wherein the printed load resistance comprising two or more resistors in parallel and a switch in series with each of said two or more resistors.

4. The printed timer label according to claim 3, wherein the switch is configured to be activated by closing a circuit.

5. The printed timer label according to claim 3, wherein the switch is configured to be activated by breaking a circuit.

6. The printed timer label according to claim 2, wherein the at least one switch is configured to be activated by closing a circuit.

7. The printed timer label according to claim 2, wherein the at least one switch is configured to be activated by breaking a circuit.

8. The printed timer label according to claim 4, wherein the switch comprises a pull tag and two activation pads, and is configured to be activated by removal of the pull tag and compression of the activation pads towards each other to close the circuit.

9. The printed timer label according to claim 6, wherein the at least one switch comprises a pull tag and two activation pads, and is configured to be activated by removal of the pull tag and compression of the activation pads towards each other to close the circuit.

10. The printed timer label according to claim 1, wherein the printed voltage comparison circuitry comprises a differential amplifier.

11. The printed timer label according to claim 1, further comprising an indication device connected to the output of the printed voltage comparison circuitry.

12. The printed timer label according to claim 11, wherein the indication device comprises a light source or an electronic display.

13. The printed timer label according to claim 11, wherein the indication device is also on the substrate.

14. The printed timer label according to claim 11, further comprising a driver configured to send a drive signal to the indication device when the output signal provided by the printed voltage comparison circuitry indicates that the output voltage of the printed battery is equal to or less than the predetermined threshold value.

15. The printed timer label according to claim 1, wherein the substrate is a flexible substrate.

16. The printed timer label according to claim 1, wherein the printed battery comprises at least one cell and a plurality of resistors connected in series.

17. The printed timer label according to claim 15, wherein the plurality of resistors output a threshold voltage at a node between first and second ones of the plurality of resistors.

18. The printed timer label according to claim 16, wherein the printed voltage comparison circuitry comprises a differential amplifier configured to receive a battery voltage from the printed load resistance and the threshold voltage, and the battery voltage from the printed load resistance is greater than the threshold voltage.

19. The printed timer label according to claim 1, wherein an output of the differential amplifier changes state when the battery voltage from the printed load resistance equals or is less than the threshold voltage.

20. The printed timer label according to claim 1, wherein the printed load resistance imparts a load on the printed battery.
